(19) United States
(12) Patent Application Publication
(10) Pub. No.: US 2023/0211795 A1
(43) Pub. Date: Jul. 6, 2023

(54) TEST MANAGEMENT SYSTEM USING DATA SET AND METHOD THEREFOR

(71) Applicant: HYUNDAI AUTOEVER CORP., Seoul (KR)

(72) Inventor: Hye Ryun Park, Seoul (KR)

(73) Assignee: HYUNDAI AUTOEVER CORP., Seoul (KR)

(21) Appl. No.: 18/083,252

(22) Filed: Dec. 16, 2022

(30) Foreign Application Priority Data
Dec. 30, 2021 (KR) 10-2021-0192274

(51) Int. Cl. B60W 50/029; B60W 50/02; G01M 15/04

(52) U.S. Cl. CPC B60W 50/029; B60W 50/0205; G01M 15/042; B60W 2050/0292

(57) ABSTRACT

Disclosed are a system and a method for managing and performing a test using a data set. More particularly, the test management system enables data to be easily managed by generating and managing data sets for each execution mode and for each test environment.

### CROSS REFERENCE TO RELATED APPLICATION

This application claims benefit of and priority to Republic of Korea Patent Application No. 10-2021-0192274, filed on Dec. 30, 2021, the disclosure of which is hereby incorporated by reference in its entirety.

### FIELD

The present disclosure relates to a test management system using a data set and a method thereof.

### BACKGROUND

The statements in this section merely provide background information related to the present disclosure and may not constitute prior art.

An environment in which a test related to a vehicle is performed may be divided into a development system, a verification system, and an operation system. The development system may mean an environment corresponding to a step of developing a test system for a vehicle. The verification system may mean an environment corresponding to a step of verifying whether a test system operates normally by simulating the test system developed in the development system. The operation system may mean an environment corresponding to a step of actually operating a system verified in the verification system.

Furthermore, a test related to a vehicle may be performed by using an actual vehicle model or may be performed by using a virtual model generated for the test.

When a test related to a vehicle is performed, setting data may be different depending on a test environment, a test purpose, a test model, or a test execution method for each vehicle.

### SUMMARY

The present disclosure improves convenience in use, prevents an error of system setting, consistently supplements and checks a test environment and test results. The present disclosure manages and removes data in a lump. The improvements may be achieved by dividing and managing data for each data set and performing a test so that a test environment can be divided, a test can be performed in an actual environment, or a test can be performed in a virtual model.

In one embodiment of the present disclosure, a test management system includes a data management circuit configured to generate data sets for each execution mode of a test management system and for each test environment of a test participation system. The system also includes a participation system management circuit configured to distribute, to the test participation system, the data sets corresponding to the execution mode and the test environment and configured to control the test participation system.

In the test management system, the test participation system may include an actual vehicle for a test and a virtual model generated for a test.

In the test management system, the execution mode may include an actual environment test mode and a simulation mode.

In the test management system, the test environment may include a development system, a verification system, and an operation system.

The test management system may further include a time setting circuit configured to periodically set, correct, and distribute time information to the data set.

In the test management system, the test participation system may include a virtual model. The test management system may further include a virtual model generation circuit configured to generate the virtual model.

In another embodiment of the present disclosure, a test execution system includes: a data management circuit configured to generate data sets for each execution mode of a test execution system and for each test environment of a test participation system. The system also includes a test participation system configured to perform a test by using the data sets. The system also includes a participation system management circuit configured to distribute, to the test participation system, the data sets corresponding to the execution mode and the test environment. The participation system management circuit is also configured to control the test participation system to perform the test. The participation system management circuit is also configured to transmit, to the data management circuit, results of the test derived by the test participation system.

The test execution system may further include a time setting circuit configured to periodically set, correct, and distribute time information to the data set.

In the test execution system, when the execution mode of the test execution system is a reproduction mode, the test participation system may reproduce a test that was performed in the past by using the results of the test.

The test execution system may further include a log management circuit configured to store log data including history information of the test from which the results of the test have been derived and transmit the log data to the data management circuit.

In the test execution system, the test participation system includes a virtual model. The test execution system may further include a virtual model generation circuit configured to generate the virtual model.

In still another embodiment, a method of managing a test management system includes: generating data sets for each execution mode of a test management system a mode of which is a setting mode and for each test environment of a test participation system. The method also includes distributing, to the test participation system, the data sets corresponding to the execution mode and the test environment. The method also includes changing the mode of the test management system into an execution mode. The method also includes performing, by the test participation system, a test. The method also includes storing results of the test derived by the test participation system.

In the method of managing a test management system, the execution mode may include an actual environment test mode and a simulation mode. The test environment may include a development system, a verification system, and an operation system.

In the method of managing a test management system, the test participation system may include an actual vehicle for a test and a virtual model generated for a test.

The method of managing a test management system may further include generating the virtual model.

In the method of managing a test management system, the mode of the test management system may be set as a setting mode, an execution mode, and a reproduction mode.

In the method of managing a test management system, the test management system may be changed from the setting mode to the execution mode or the reproduction mode and changed from the execution mode or the reproduction mode to the setting mode.

As described above, according to the present embodiment, convenience of use of data can be improved and a setting error can be prevented by dividing and managing the data for each data set. The results of a test can be consistently supplemented and checked through a consistent test environment construction. Data can be managed and removed in a lump. Furthermore, it is possible to perform and reproduce a test for a desired model by using a virtual model for a model for which it is difficult to obtain an actual model.

### BRIEF DESCRIPTION OF THE DRAWINGS

In order that the disclosure may be well understood, there will now be described various forms thereof, given by way of example, reference being made to the accompanying drawings, in which:

FIG. 1 is a diagram for describing a test management system and a test participation system according to an embodiment of the present embodiment;

FIG. 2 is a diagram for describing a mode and test environment in which the test management system according to an embodiment of the present embodiment may be set;

FIG. 3 is a diagram for describing modes that are included in an execution mode according to an embodiment of the present embodiment; and

FIG. 4 is a diagram for describing a method of managing the test management system according to the present embodiment.

The drawings described herein are for illustration purposes only and are not intended to limit the scope of the present disclosure in any way.

### DETAILED DESCRIPTION

Hereinafter, some embodiments are described in detail with reference to drawings. In adding reference numerals to the elements of each drawing, it should be noted that the same elements have the same or equivalent reference numerals as much as possible even if they are displayed in different drawings. Furthermore, in describing embodiments of the present disclosure, when it is determined that a detailed description of the related well-known configuration or function hinders understanding of an embodiment of the present disclosure, the detailed description thereof has been omitted.

Furthermore, in describing elements of an embodiment of the present disclosure, terms, such as a first, a second A, B, (a), and (b), may be used. Such terms are used only to distinguish one component from another component, and the essence, order, or sequence of a corresponding component is not limited by the terms. When it is said that one component is “connected”, “combined”, or “coupled” to another component, the one component may be directly connected or coupled to another component, but it should also be understood that a third component may be “connected”, “combined”, or “coupled” between the two components.

When a component, device, element, or the like of the present disclosure is described as having a purpose or performing an operation, function, or the like, the component, device, or element should be considered herein as being “configured to” meet that purpose or to perform that operation or function.

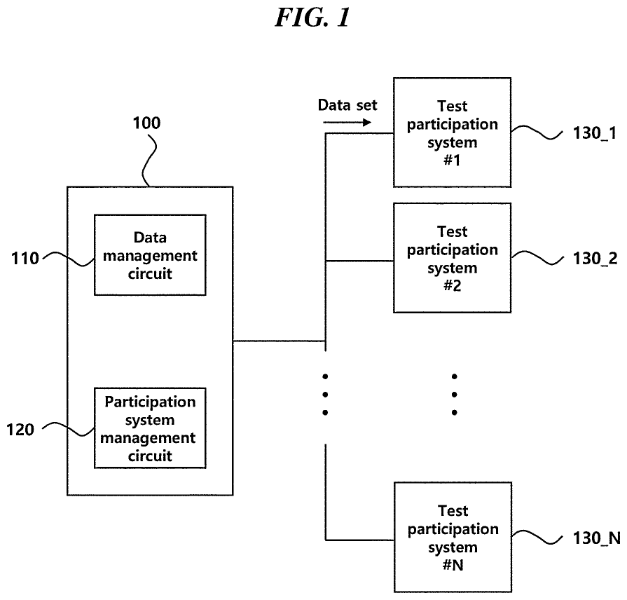

FIG. 1 is a diagram for describing a test management system and a test participation system according to an embodiment of the present embodiment.

A test management system 100 according to the present embodiment may be a system for managing test participation systems 130_1, 130_2 to 130_N for performing a test on a vehicle. In this case, the test participation system that performs a test may be one or two or more, and thus N may be a natural number equal to or greater than 1.

The test management system 100 may include a data management circuit 110 and a participation system management circuit 120. In addition, the test management system 100 may include a virtual model generation circuit to generate virtual models.

The data management circuit 110 may generate data sets by using individual data that has been previously stored and that is related to a test for a vehicle. The data sets may be divided and generated for each test environment of the test participation systems 130_1, 130_2 to 130_N and for each execution mode, i.e., modes of the test participation systems 130_1, 130_2 to 130_N. The test environment may include a development system, a verification system, and an operation system. The execution mode may include an actual environment test mode and a simulation mode. In other words, the data sets may be divided and set for each execution mode and may be divided and set for each test environment within each execution mode. The reason for this is that information of a system, an IP, and a routing path may be differently set for each test environment within each execution mode, for example. Each data set may have a unique identification (ID) for each execution mode or for each test environment within each execution mode.

In the execution mode of the test management system, a model included in the test participation system may be different depending on whether the model is an actual vehicle or a virtual model. Accordingly, it is necessary to divide data, which may be used in a test, into data sets and manage the data sets.

For example, a data set to be used in a verification system test environment may be generated. A data set to be used in a reproduction mode may be generated. Data sets to be used in a development system and an actual environment test mode may be generated. This may be performed if the test management system is a setting mode.

The data set that is generated by the data management circuit 110 may include the results of a test for each of the test participation systems 130_1, 130_2 to 130_N. Accordingly, when the test participation system performs a test, a data set corresponding to the results of the test may be distributed to the test participation system, so that the test participation system may reproduce the past test.

After setting related to a data set in the data management circuit 110, the participation system management circuit 120 may set a mode of the test management system as the execution mode. The test environment of each of the test participation systems 130_1, 130_2 to 130_N may correspond to one of the development system, the verification system, or the operation system. The participation system management circuit 120 may have a mode corresponding to one of an actual environment test mode, i.e., the execution mode, and the simulation mode with respect to each of the test participation systems 130_1, 130_2 to 130_N. The participation system management circuit 120 may distribute a corresponding data set to the test participation system so that the test participation system can perform a test. The actual environment test mode may be a mode that is set when the test participation system uses an actual vehicle. The simulation mode may be a mode that is set when the test participation system uses a virtual model. The reproduction mode is a mode in which a test that was performed in the past is repeatedly performed, and the reproduction mode may be set when the test participation system uses an actual vehicle or the virtual model.

Furthermore, the participation system management circuit 120 may distribute a data set to the test participation system and may also monitor whether the data set has been distributed normally.

The participation system management circuit 120 may control the test participation systems 130_1, 130_2 to 130_N. In other words, after distributing corresponding data sets to the test participation systems 130_1, 130_2 to 130_N, the participation system management circuit 120 may control the test participation systems 130_1, 130_2 to 130_N so that the test participation systems 130_1, 130_2 to 130_N perform tests by using the data sets. The participation system management circuit 120 may control the test participation systems 130_1, 130_2 to 130_N so that the test participation systems 130_1, 130_2 to 130_N stop tests. Furthermore, the participation system management circuit 120 may check whether the test participation system has completed the download of a data set by distributing the data set. If the download of the data set fails, the participation system management circuit 120 may monitor the test participation system so that the test participation system reattempts the download. The participation system management circuit 120 may set a mode of the test management system. A mode of the test management system may be set as one of the setting mode, the execution mode, or the reproduction mode. The setting mode may be changed into the execution mode or the reproduction mode. The execution mode or the reproduction mode may be changed into the setting mode.

The test participation systems 130_1, 130_2 to 130_N may use an actual vehicle (or an actual model) for a test and may use a virtual model generated for a test. Accordingly, the data management circuit 110 that generates a data set may generate data sets for the actual environment test mode and the simulation mode, respectively, and the data management circuit 110 may separately manage the data sets. The data management circuit 110 may generate data sets for test environments within the actual environment test mode and the simulation mode, respectively, and may separately manage the data sets. The virtual model may be an emulator instead of an actual interface system for a test and may be a model that replaces a vehicle.

The test management system 100 may further include a time setting circuit (not illustrated) for periodically setting, correcting, and distributing time information to a data set. Accordingly, when a test is performed and the results of the test are stored in the test participation system, the time setting circuit may distribute time information for the time when the test was performed to a data set corresponding to the results of the test. Accordingly, the corresponding data set may further include the time information. Accordingly, since the data set that is generated by the data management circuit 110 further includes the time information, each data sets can be managed for each time. For example, the time setting circuit may be a network time protocol (NTP) server.

The test management system 100 may be further connected to a log management circuit (not illustrated). When a data set is distributed to each of the test participation systems 130_1, 130_2 to 130_N and each of the test participation systems 130_1, 130_2 to 130_N performs a test, the log management circuit may collect log data including information on the test execution history of each of the test participation systems 130_1, 130_2 to 130_N. Furthermore, thereafter, when the test management system 100 reproduces the corresponding test, the log management circuit provides the log data, so that the same test as the past test can be reproduced.

Additionally, a test execution system (not illustrated) that uses the test management system 100 may include a data management circuit, a test participation system, and a participation system management circuit. In addition, the test execution system may include a virtual model generation circuit to generate virtual models. The results of a test that are derived by the test participation system may be transmitted to the data management circuit. The data management circuit may generate the results of the test again as a data set, so that the results of the test can be subsequently used when the same test is reproduced. Accordingly, the past test data may also be stored and managed as a data set for the reproduction mode.

The test execution system may be further connected to the log management circuit (not illustrated). When a data set is distributed to each of the test participation systems and the test participation system performs a test, the log management circuit may collect log data including information on the test execution history of each of the test participation systems. Furthermore, when the test management system 100 subsequently reproduces the corresponding test, the log management circuit provides the log data, so that the same test as the past test can be reproduced.

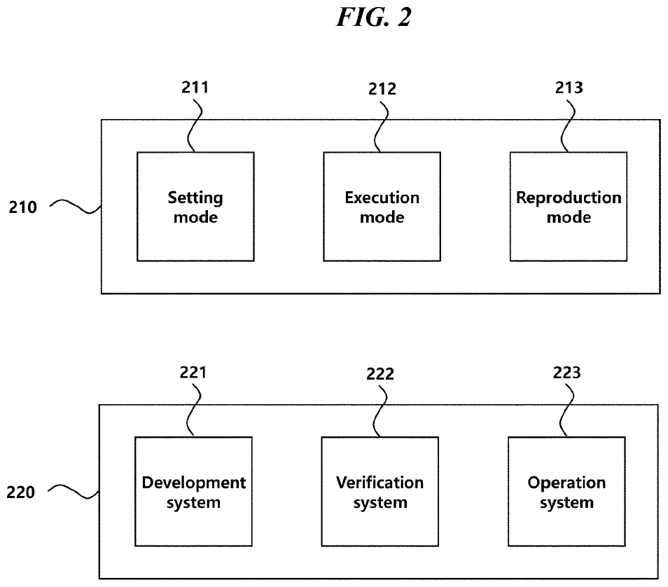

FIG. 2 is a diagram for describing a mode and test environment in which the test management system according to the present embodiment may be set.

A model mode 210 in which the test management system according to the present embodiment may be set may include a setting mode 211, an execution mode 212, and a reproduction mode 213.

The setting mode 211 may be a mode in which the test management system distributes, to the test participation system, data sets corresponding to the execution mode 212 and the test environment 220.

The execution mode 212 may be a mode in which the test participation system performs a test. Specifically, the execution mode 212 may include the actual environment test mode and the simulation mode, which are divided depending on the properties of the test participation system and the purpose of a test thereof.

In the execution mode 212 of the test management system, it is necessary to divide and manage data which may be used in a test as a data set because the execution mode 212 may be different depending on whether a model included in the test participation system is an actual vehicle or a virtual model.

The reproduction mode 213 may be a mode in which the test participation system reproduces a past test. In other words, if a mode of the test management system is the reproduction mode 213, the test management system may repeatedly perform the past test or the contents of the past test may be simply played back. Furthermore, in the reproduction mode 213, a process of playing back the content of the past test that have been recorded through a separate display device not the test participation system may be performed.

Modes of the test management system and the test execution system may be changed from the setting mode 211 to the execution mode 212 or the reproduction mode 213 and may be changed from the execution mode 212 or the reproduction mode 213 to the setting mode 211.

Furthermore, the test environment 220 to which the test participation system according to the present embodiment may correspond may include a development system 221, a verification system 222, and an operation system 223.

The development system 221 may mean an environment corresponding to a step of developing a test system for a vehicle. The verification system 222 may mean an environment corresponding to a step of verifying whether a test system operates normally by simulating the test system developed in the development system. The operation system 223 may mean an environment corresponding to a step of actually operating a system that has been verified by the verification system.

Accordingly, the test participation system may perform a test by identifying in which environment the test will be performed based on the test environment 220. Since the results of the test are derived for each set test environment 220, the results of the test may also be divided and managed as a data set.

Specifically, the data sets may be divided and generated for each test environment 220 and for each execution mode 212 of the model mode 210. The test environment 220 of the test participation system may correspond to one of the development system 221, the verification system 222, or the operation system 223. The execution mode 212 of the data management system may be set as one of the actual environment test mode or the simulation mode. In other words, the data sets may be divided and set for each execution mode 212 and may be divided and set for each test environment 220 within the execution mode 212. Each data set may have a unique ID for each test environment within the execution mode. Furthermore, the data set may include, as a data set, data corresponding to the reproduction mode 213 that reproduces a test for data on which the test was performed in the past.

For example, a data set to be used in a test environment of the verification system 222 may be generated. A data set to be used in the reproduction mode 213 may be generated. A data set to be used in the development system 221 and the actual environment test mode included in the execution mode 212 may be generated.

Accordingly, if data that is used when tests for the development system 221 and the verification system 222 are performed is the same, but only data for the execution environment is different, in order to improve convenience of duplication or management therefor, a test may be performed by selecting and distributing a data set that has been set for each mode. Accordingly, there may be an advantage from a convenience aspect.

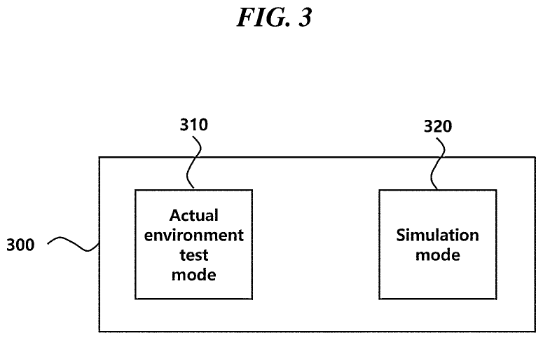

FIG. 3 is a diagram for describing modes that are included in the execution mode according to the present embodiment.

The execution mode 300 in which the test management system may be set may include the actual environment test mode 310 and the simulation mode 320.

The actual environment test mode 310 is a mode, which may be set when an actual model not a virtual model is used in the test participation system. The test management and execution systems according to the present embodiment need to identify whether data stored, specifically, in the test management system is data to be used for an actual vehicle or data to be used for a virtual model. Accordingly, the actual environment test mode 310 may be set in the test management system. Accordingly, it is necessary to separately generate a data set for a test that will be performed by using an actual vehicle.

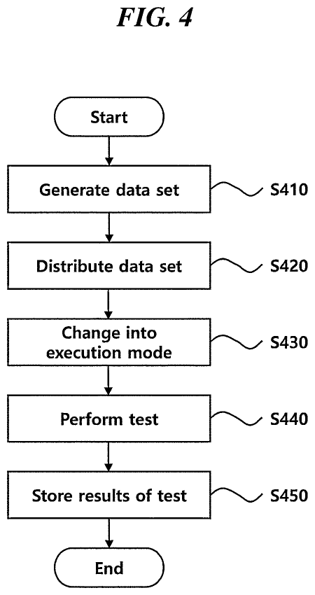

The simulation mode 320 is a mode, which may be set when a virtual model not an actual vehicle is used in the test participation system. It is impossible to obtain all test models and to perform a test on a service or there are many difficulties, such as a high cost, in performing test reproduction related to safety. Accordingly, if a test is performed by using a virtual model, data similar to an actual vehicle can be obtained. Accordingly, the simulation mode 320 may be set in the test management system. For this reason, it is necessary to separately generate a data set for a test to be performed by using the virtual model. FIG. 4 is a diagram for describing a method of managing the test management system according to the present embodiment.

In the method of managing the test management system according to the present embodiment, a mode of the test management system is the setting mode. Step S410 of generating data sets for each execution mode of the test management system and for each test environment of the test participation system may be performed.

The test environment may include the development system, the verification system, and the operation system. The execution mode may include the actual environment test mode and the simulation mode. In other words, the data sets may be divided and set for each execution mode and may be divided and set for each test environment within the execution mode. Each data set may have a unique ID for each test environment within the execution mode.

The execution mode of the test management system may be different depending on whether a model included in the test participation system is an actual vehicle or a virtual model. Accordingly, it is necessary to divide and manage data which may be used in a test as a data set.

For example, a data set to be used in the test environment of the verification system may be generated, and data sets to be used in the development system and the actual environment test mode may be generated.

The test participation system may include an actual vehicle for a test and a virtual model generated for a test. If the test participation system includes a virtual model, a step (not illustrated) of generating the virtual model for a test may further be performed. A virtual model may be generated based on the existing data under a condition in which it is difficult to perform a test because data is not actually generated or the probability that data will be actually generated is low, and the test may be performed.

Step S420 of distributing, to the test participation system, data sets corresponding to the execution mode and the test environment may be performed. As described above, since a test is performed by using data sets generated based on the test environment and the execution mode, there are advantages in the management of data, the repetitive execution of a test, and reproduction.

Step S430 of changing a mode of the test management system into the execution mode may be performed.

The execution mode in which the test management system may be set may be divided into the actual environment test mode and the simulation mode depending on the properties of the test participation system. In other words, if the test participation system performs a test using an actual vehicle, a mode of the test participation system may be the actual environment test mode. If the test participation system performs a test using a virtual model, a mode of the test participation system may be the simulation mode.

Step S440 of performing, by the test participation system, a test may be performed.

Step S450 of storing the results of the test derived by the test participation system may be performed. The stored results of the test may be stored as a data set and may be subsequently used when a test that has already been performed through the test management system is reproduced.

The term “include”, “constitute” or “have” described above, unless specially mentioned otherwise, means that a corresponding component may be included. Accordingly, it should be interpreted that the term may further include another component without excluding another component. All terms used herein, including technical terms or scientific terms, have the same meanings as those commonly understood by a person having ordinary knowledge in the art to which the present disclosure pertains, unless defined otherwise in the present disclosure. Terms that are commonly used, such as those defined in dictionaries, should be construed as having the same meanings as those in the context of a related technology and should not be construed as ideal or excessively formal meanings unless explicitly defined otherwise in the application.

The above description is merely a description of the technical spirit of the present disclosure, and those having ordinary skill in the art may change and modify the present disclosure in various ways without departing from the essential characteristic of the present disclosure. Accordingly, the embodiments described in the present disclosure should not be construed as limiting the technical spirit of the present disclosure but should be construed as describing the technical spirit of the present disclosure. The technical spirit of the present disclosure is not restricted by the embodiments. The scope of protection of the present disclosure should be construed based on the following claims, and all of technical spirits within an equivalent range of the present disclosure should be construed as being included in the scope of protection of the present disclosure.

What is claimed is:

1. A test management system comprising:
a data management circuit configured to generate data sets for each execution mode of a test management system and for each test environment of a test participation system; and
a participation system management circuit configured to distribute, to the test participation system, the data sets corresponding to the execution mode and the test environment and configured to control the test participation system.

2. The test management system of claim 1, wherein the test participation system comprises an actual vehicle for a test and a virtual model generated for a test.

3. The test management system of claim 1, wherein the execution mode comprises an actual environment test mode and a simulation mode.

4. The test management system of claim 1, wherein the test environment comprises a development system, a verification system, and an operation system.

5. The test management system of claim 1, further comprising a time setting circuit configured to periodically set, correct, and distribute time information to the data sets.

6. The test management system of claim 1, wherein:
the test participation system comprises a virtual model, and
the test management system further comprises a virtual model generation circuit configured to generate the virtual model.

7. A method of a test, comprising:
generating data sets for each execution mode of a test management system a mode of which is a setting mode and for each test environment of a test participation system;
distributing, to the test participation system, the data sets corresponding to the execution mode and the test environment;
changing the mode of the test management system into an execution mode;
performing, by the test participation system, a test; and
storing results of the test derived by the test participation system.

8. The method of claim 7, wherein:
the execution mode comprises an actual environment test mode and a simulation mode, and
the test environment comprises a development system, a verification system, and an operation system.

9. The method of claim 7, wherein the test participation system comprises an actual vehicle for a test and a virtual model generated for a test.

10. The method of claim 7, wherein:
the test participation system comprises a virtual model, and
the method further comprises generating the virtual model.

11. The method of claim 7, wherein the mode of the test management system is configured to be set as a setting mode, an execution mode, or a reproduction mode.

12. The method of claim 11, wherein the test management system is configured to be changed from the setting mode to the execution mode or the reproduction mode and changed from the execution mode or the reproduction mode to the setting mode.
